(19) United States
(12) Patent Application Publication
(10) Pub. No.: US 2015/0014708 A1
(43) Pub. Date: Jan. 15, 2015

(54) PACKAGE FOR LIGHT EMITTING AND RECEIVING DEVICES

(71) Applicants: Ingo Speier, Victoria (CA); Ian Ashdown, West Vancouver (CA); Philippe Schick, Vancouver (CA)

(72) Inventors: Ingo Speier, Victoria (CA); Ian Ashdown, West Vancouver (CA); Philippe Schick, Vancouver (CA)

(21) Appl. No.: 14/334,189

(22) Filed: Jul. 17, 2014

Related U.S. Application Data
(63) Continuation of application No. 13/515,620, filed on Oct. 2, 2012, now abandoned.
(60) Provisional application No. 61/293,777, filed on Jan. 11, 2010.

(51) Int. Cl. H01L 25/16; H01L 33/50; H01L 33/58; H01L 33/62; H01L 33/48; H01L 33/60; H01L 33/54

(52) U.S. Cl. CPC H01L 25/167; H01L 33/60; H01L 33/507; H01L 33/54; H01L 33/62; H01L 33/486; H01L 33/58
USPC 257/80; 257/88

(57) ABSTRACT

In various embodiments, packages include one or more lighting devices having electrical contact points, a flexible substrate for supporting the lighting devices, a plurality of electrically conductive traces defined on the substrate and electrically connected to the contact points of the lighting devices, and an adhesive layer mounting each of the lighting devices on the substrate.

### TECHNICAL FIELD

The subject matter of the present invention relates to the field of opto-electronic packaging, and more particularly, is concerned with a package for light emitting devices, including, but not limited to, light emitting diodes (LEDs).

### BACKGROUND ART

A package for light emitting devices, for example, semiconductor die such as LEDs, must serve at least the following five main functions. First, the package needs to provide a mechanical base upon which the die can be placed. Second, the package needs to provide a thermal path to allow waste heat to be extracted from the die. Third, the package needs to provide an optical path which allows for light extraction from the die. Fourth, the package needs to provide protection of the die from the environment. Fifth, the package needs to provide electrical connection to the die.

Traditionally, LED die range in size from ˜300 um (micrometers) edge length up to several millimeters in edge length and are packaged individually or in densely packed groups in order to provide the functions described above at the lowest possible cost. In general, the larger the package, the more expensive it is to produce, especially as increasing thermal and optical requirements have required the use of special materials. Individual handling and processing of die also leads to a higher overall package cost. Finally, once those packages are assembled at the system level, further cost is incurred to electrically and mechanically connect them, provide adequate heat sink capability to keep them cool, and provide optical control of the light that is generated by the die of the packages.

There remains a need for solutions to package design for light emitting devices that will substantially achieve the five functions described above.

### SUMMARY OF THE INVENTION

The present invention provides solutions for design of a package for light emitting devices and, in particular, for semiconductor dice such as micro-LEDs (uLEDs), which are defined as light emitting diodes with an edge length less than ˜300 um. These solutions include specific ways of configuring and integrating different elements of the package to achieve enhanced performance and/or cost characteristics.

In accordance with an aspect of the present invention, the package includes one or more lighting devices having electrical contact points, a substrate for supporting the lighting devices, a plurality of electrically conductive traces defined on the substrate so as to provide electrical contacts in close proximity to the contact points of the lighting devices, a planarization layer applied on the substrate so as to cover at least the conductive traces thereon, and a conductive layer deposited over the contact points on each of the lighting devices and the electrical contacts of the conductive traces so as to electrically interconnect the respective devices and traces to provide a circuit path for supply of electrical drive power to the lighting devices via the conductive traces. A layer of phosphor material can be applied to a second surface of the substrate to convert light emitted by the devices from one to another color.

In accordance with another aspect of the present invention, the package includes one or more lighting devices having electrical contact points, a substrate for supporting the lighting devices, an adhesive layer mounting each of the lighting devices on the substrate, and a conductive layer deposited over the contact points on each of the lighting devices so as to electrically interconnect the respective lighting devices to provide a circuit path for supply of electrical drive power to the lighting devices. Also the substrate may be transparent and a surface of the lighting devices not in contact with the substrate may form a reflector for reflecting light towards the substrate.

In accordance with a further aspect of the present invention, the package includes one or more lighting devices having electrical contact points, a substrate for supporting the lighting devices on a first side thereof and having one or more electrically conductive pads on a second side thereof, one or more electrically conductive paths connecting one or more of the electrical contact points of the lighting devices to one or more of the electrically conductive pads, and an encapsulation layer applied on the first side and at least over the electrically conductive paths on the first side.

Light emitting devices in the form of uLEDs so packaged, if operated at similar current densities to large-format die (˜1 mm edge length), will generate approximately one one-hundredth of the quantity of heat. Provided the uLEDs are not closely packed, the thermal load can be easily managed through a variety of cost effective materials (including but not limited to glass, plastic, ceramics, etc.) rather than through traditional, relatively expensive, thermal management materials or techniques. Also, the uLEDs provide optical benefits in that they typically have higher light extraction efficiencies (leading to higher overall efficiency) and they enable the use of micro-optics, which are generally easier to integrate into the package.

### BRIEF DESCRIPTION OF THE DRAWINGS

For clarity, the drawings herein are not necessarily to scale, and have been provided as such in order to illustrate the principles of the subject matter, not to limit the invention.

FIG. 1 is a schematic sectional view of an exemplary embodiment of a portion of a package including a light emitting device.

FIG. 2A is a schematic view depicting a radial pattern of light extraction from a circular-shaped light emitting device.

FIG. 2B is a schematic view of multiple circular-shaped light emitting devices arranged with a close packing density.

FIG. 3A is a schematic view depicting a radial pattern of light extraction from a hexagonal-shaped light emitting device.

FIG. 3B is a schematic view of multiple hexagonal-shaped light emitting devices arranged with a close packing density.

FIGS. 4A-4E are schematic views of different arrangements of multiple light emitting devices with different shapes created by patterning during epitaxial growth.

FIG. 5A is a schematic view of a circular-shaped light emitting device with a serrated peripheral edge created by patterning during epitaxial growth.

FIGS. 5B and 5C are schematic views of differently-shaped light emitting devices produced by patterning during epitaxial growth in a direction perpendicular to the direction of epitaxial growth in FIG. 5A.

FIG. 6 is a schematic view depicting a total internal reflection path within a light emitting device.

FIG. 7 is a schematic view of a light emitting device having a random pattern produced on at least one surface such as by roughening the surface either prior to or after epitaxial growth.

FIG. 8 is a schematic view of an exemplary embodiment of a light emitting device incorporated in a wave-guiding structure.

FIG. 9 is a schematic view of another exemplary embodiment of a light emitting device incorporated in a wave-guiding structure.

FIGS. 10A and 10B are schematic views of stages in producing a roughened surface on an epitaxial layer forming a light emitting device.

FIGS. 11-14, 15A and 15B are schematic views of stages in using different techniques to apply phosphor to a light emitting device or substrate that will incorporated into a package.

FIGS. 16, 17, 18A and 18B are schematic views of different exemplary embodiments of packages incorporating light emitting devices with phosphor layers at various locations relative to the device.

FIGS. 19A, 19B and 20 are schematic views of different exemplary embodiments of packages incorporating a transparent substrate with a mesa integrally molded thereon which mounts a light emitting device.

FIGS. 21-26 are schematic views of different exemplary embodiments of packages incorporating different light reflecting and extracting features.

FIGS. 27 and 28 are schematic views of exemplary embodiments of packages incorporating light emitting devices and spaced transparent substrates respectively without and with a light concentrating diffuser therebetween.

FIG. 29 is a flow diagram of process steps to form interconnects between light emitting devices.

FIG. 30 is a schematic view of an exemplary embodiment of a package having phosphor dots applied to less than all of the light emitting devices.

FIG. 31 is a schematic view of a source substrate carrying an array of light emitting devices.

FIG. 32 is a schematic view of a pickup tool used to transfer the array of light emitting devices from the source substrate of FIG. 31.

FIG. 33 is a schematic view of a target substrate to which the array of light emitting devices of FIG. 31 have been transferred by the pickup tool of FIG. 32.

FIGS. 34 and 35 are schematic plan and side views, respectively of an exemplary embodiment of a package with an array of interconnected light emitting devices.

FIGS. 36-41 are schematic views of exemplary embodiments of packages of arrays of light emitting devices with different configurations.

FIGS. 42 and 43 are schematic views of exemplary embodiments of other light emitting device packages.

### DESCRIPTION OF EMBODIMENTS

It should be understood that the light emitting devices, which the package to be described herein is designed to accommodate, may be any device that emits electromagnetic radiation within a wavelength regime of interest, for example, the visible, infrared or ultraviolet regime, when activated by applying a potential difference across the device or passing a current through the device. Although the above-mentioned uLEDs will be the primary light emitting devices discussed in this detailed description, other examples of such light emitting devices include solid-state, organic, polymer, phosphor coated or high-flux LEDs, laser diodes or other similar devices as would be readily understood. The output radiation of the light emitting devices may be visible, such as red, blue or green, or invisible, such as infrared or ultraviolet. The light emitting devices may produce radiation of a spread of wavelengths. The light emitting devices may be made up of multiple LEDs, each emitting substantially the same or different wavelengths.

It should also be understood that the packages described herein can accommodate light receiving devices as well as light emitting devices. Such light receiving devices include but are not limited to photovoltaic cells, photo sensors and solar thermal pickups. In a light receiving package the optical system will concentrate light incident to the package on the light receiving devices in the package. It should also be understood that the package may contain both light emitting devices and light receiving devices (“hybrid packages”). The following embodiments focus on light emitting packages, but it is understood that the same concepts apply to light receiving and hybrid packages. A device may be both a light emitting device and a light receiving device and these devices may also be accommodated in the package.

The term lighting device referred to herein includes light emitting devices, light receiving devices and where more than one lighting device is referenced may include any combination of light receiving devices and light emitting devices.

Very small, compact packages may be made that include one or more uLED chips. A package of microLED chips may be used or treated as a single, non-microLED chip. A benefit of a microLED package over a microLED chip is that a number of untested uLEDs may be packaged in a uLED package which is subsequently tested, resulting in reduced time and cost for characterization and a reduction in the need for extensive binning of the packages.

A microLED package may contain between 1 and 20, possibly more uLED chips. Each chip may have, for example, lateral dimensions of 150 μm and thicknesses of 15 μm or less. Other chip dimensions falling into the size range of uLEDs may also be used. MicroLED packages may be smaller than non-microLED dies.

The microLED package may contain one or more uLEDs with substantially the same chromaticity. In other embodiments, uLEDs with different chromaticities may be included in the same package. The uLED package may or may not contain one or more optical conversion layers such as phosphors. The uLED package may have one or more encapsulation layers, and/or may comprise primary optics.

Depending on the number of uLEDs in the package and the selection of substrate material, a uLED package may be made with linear dimensions under 300 μm and a thickness less than 15 μm.

It also should be understood that, in order to produce similar levels of light as produced by a large format LED, many more uLEDs have to be employed. The packaging techniques that are disclosed hereinafter are compatible with large panel processing techniques, such as used in the display industry or in ‘roll-to-roll’ processing, to create very large sheets or panels with thousands of uLEDs. Such large sheets with many uLEDs combined with suitable drive/control components form a lighting system capable of being produced at much lower cost than a lighting system using large-format LEDs, in part because no further optical or thermal components are required.

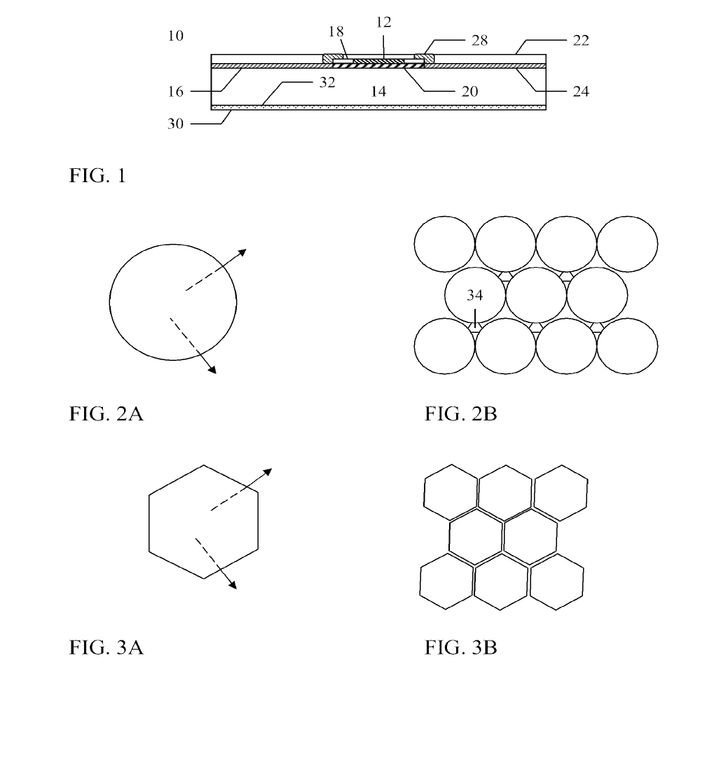

Referring now to the drawings, and particularly to FIG. 1, in accordance with the present invention there is shown an exemplary or general embodiment of a package (a portion of which is shown), generally designated 10, which includes light emitting devices 12. For simplicity's sake, only one light emitting device 12, for example a single uLED, is shown in FIG. 1. The package 10 further includes a substrate 14, such as one made of a suitable material exhibiting transparency such as glass or a plastic film. Package 10 also includes a plurality of electrically conductive traces 16 pre-deposited on substrate 14 in order to bring electrical contact points 18 on traces 16 into close proximity to the locations of devices 12. Conductive traces 16, made of a suitable conductive material, such as a metal, may be laid out on the substrate 14 in any number of configurations that will allow supply of electrical drive power to the light emitting devices 12, or strings thereof, in the desired manner.

The package 10 further includes an adhesive layer 20 and a planarization or encapsulation layer 22 to properly place each of the devices 12 on a first surface 24 of the substrate 14. Each light emitting device 12 is mounted on the first surface 24 of the substrate 14 by the adhesive layer 20. Once each device 12 is so placed the layer 22 is applied on the first surface 24 of the substrate 14 to cover and thereby electrically isolate and planarize or encapsulate at least the conductive traces 16. Selected portions of the layer 22 adjacent to the light emitting device 12 are removed to expose the contact points 18 on the devices 12 and the adjacent pre-deposited metal layers forming the conductive traces 16. A conductive layer 28 is then deposited over the adjacent sets of contact points 18 and conductive traces 16 to provide a circuit path that interconnects each device 12 to its adjacent pre-deposited conductive trace 16. Lastly, in this exemplary embodiment a layer 30 of phosphor material is applied to a second surface 32 of the substrate 14. The bottom emitting devices 12, when they are uLEDs, emit light in the blue or ultraviolet (UV) range towards and through the substrate 14. The phosphor layer 30 is used to convert at least a portion of the light emitted by the devices 12 to another color (or combination of colors) to produce white light.

Based on the general embodiment of the package 10 described above in reference to FIG. 1, there are several features of the package 10 that can be modified or enhanced based on the desired outcome. These features will now be covered in more detail with the understanding that each configuration could be integrated into a package with similar construction as the general embodiment described above. These features of the package 10 that will be covered in more detail hereinafter are as follows:

1) uLED Die—there are several variations of uLED die that could be used to efficiently generate light at the appropriate wavelengths. As well, different strategies could be used to increase the performance of the die.

2) Optics/Phosphors—different phosphor and optics can be integrated in order to reduce the cost, or enhance the performance of the package.

3) Substrate—several variations on the type and properties of the substrate can be used to enhance cost and performance of the package.

4) Interconnects—different interconnect strategies can be taken in order provide electrical contact to the die, each of which can be changed to enhance performance and cost.

5) System—there are different approaches that can be taken to integrate drive components and provide different output and levels of control.

Feature 1—uLED Die

In contrast to large format LED chips, uLEDs can benefit from their smaller size by having enhanced optical extraction efficiency. In general, uLEDs are less than ˜300 um in edge length. Several design considerations, in addition to the inherent advantages of using small, thin chips, are available to further enhance the performance of uLEDs:

A. Shaping of the uLED

B. Surface roughening or patterning

C. Design and inclusion of mirror layers

A. Shaping—One of the benefits of the uLED technology being employed is that the uLED is designed to be released from the source wafer. Basically, that means that the uLED chips do not need to be cut into individual die by traditional methods of dicing the source wafer with a saw or cleaving. The uLEDs are etched out of the source wafer, then released during a pickup process. As the uLEDs are etched, their shape can be designed in order to define light extraction in ways that is not possible with traditional diced square or rectangular uLEDs.

Referring to FIGS. 2A, 3A and 2B, 3B, there are two main considerations for the shaping process: one is light extraction from the uLEDs; and the other is the utilization factor of the epiwafer due to the achievable packing density of the uLEDs. With respect to light extraction from the uLEDs, FIGS. 2A & 3A show two different patterns of light extraction from uLEDs 12 having respective circular and hexagonal shapes. With respect to the utilization factor, FIGS. 2B & 3B show the close spacing of the uLEDs that is achievable by their adoption of respective circular and hexagonal shapes. Circular uLED shape and packing can reach a fill factor of up to 90.7% and use the empty spaces to create anchor structures 34 to support the uLEDs prior to pickup off the source wafer. The hexagonal shape of the die will allow for a two-dimensional fill factor of unity, and may also prevent “whispering gallery” modes of internal light reflection that reduce light extraction efficiency from the uLED die.

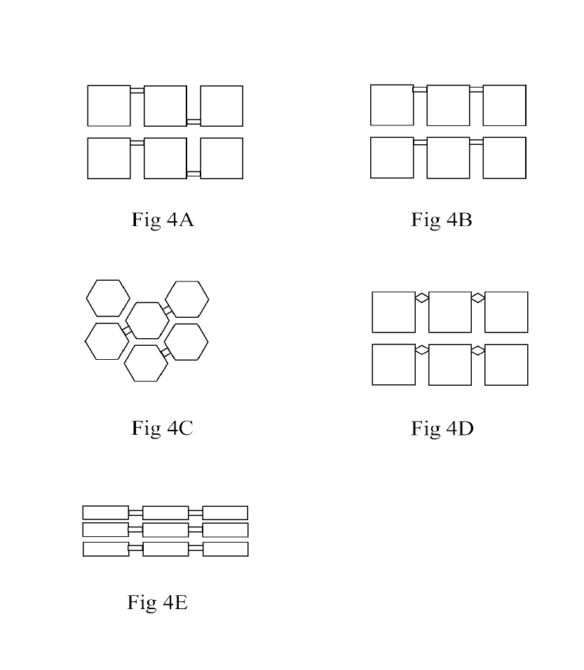

Referring to FIGS. 4A-4E, patterning of the epitaxial substrate (not shown) creates islands that approximately define the size and shape of the uLED dice 12 that are created during the epitaxial growth process. The patterning process such as dry etching allows for a wide variety of sizes and shapes. FIGS. 4A, 4B and 4D illustrate a square shape, FIG. 4C a hexagonal shape, and FIG. 4E a rectangular shape. It is understood that also circular, elliptical, triangular, octagonal, compound shapes, irregular shapes or other shapes known to people skilled in the art can be utilized. The size and shape of the uLED die can be enhanced for parameters such as epitaxial usage and die performance. In the example of FIG. 4E, the rectangular uLED die is provided with a large length over width ratio, which may beneficially affect uLED performance in terms of low thermal resistance and short mean paths for the emitted photons. Furthermore a rectangular or square shape provides high wafer utilization. In a different example, the uLED die edge length of a square shape could be 100 μm, in another the uLED die edge length could be any value included within the range of approximately 25 μm to 300 μm, and in yet another example, the uLED die edge length could be a value outside this range. In another embodiment, the uLED has a hexagonal design (FIG. 4C).

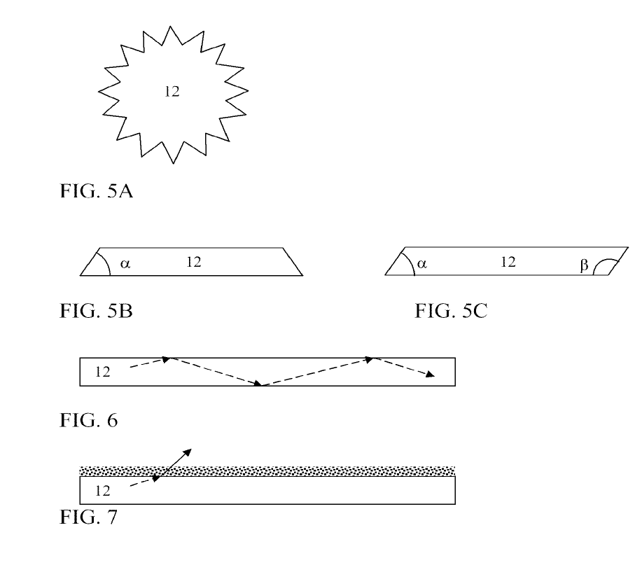

As seen in FIG. 5A, a generally circular circumferential shape with a serrated edge 36 could also be used. In addition to shaping the circumference of the uLED 12 in the epitaxial growth plane, it is also possible to shape the uLED 12 perpendicular to this direction, as seen in FIGS. 5B & 5C. The vertical etch angles α and/or β can be optimized to maximize light extraction.

B. Roughening—The uLED performance can be further enhanced by creating features that break the total internal reflection (TIR) angle within the epi layers (FIG. 6) and allow light to escape the structure (FIG. 7). Any of the following processes may be utilized for doing so: (a) etching a random pattern into the uLED chip (surface roughening); (b) etching a regular pattern (such as pyramidal); or (c) creating a photonic crystal pattern that will enhance output coupling of the beam. One approach that can be used is to create a pattern on the growth substrate prior to the epi growth process. This roughening may have a random, designed, semi-random, or partially designed and partially random pattern and can transfer to both surfaces of the epitaxy. Another approach is to roughen the external surface of the epitaxy after growth. As known to those skilled in the art, surface roughening can reduce the effective index of refraction of the emitting surface of the uIED device and so improve light extraction efficiency.

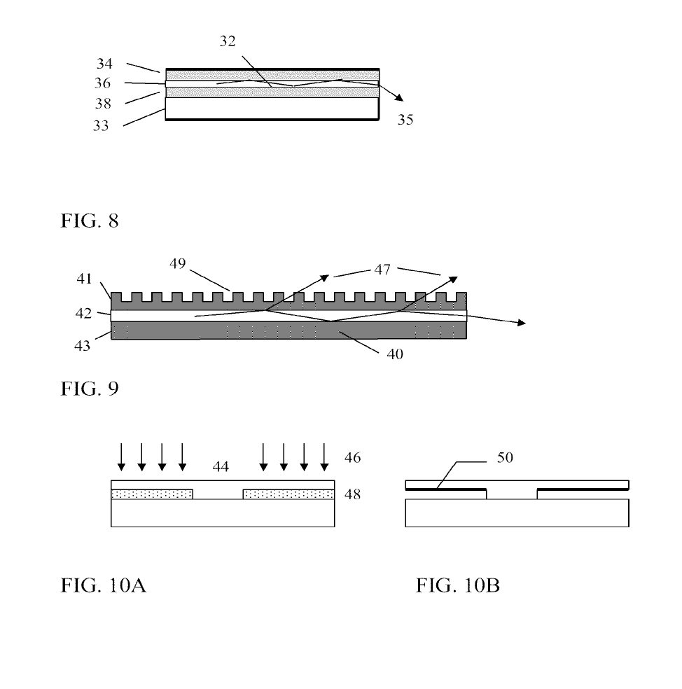

In yet another approach the epitaxial layer can be designed as a wave-guiding structure. FIG. 8 displays for example a uLED 32 with a wave-guiding structure disposed on a substrate 33. The uLED 32 includes an active layer 36 sandwiched between an upper cladding layer 34 and a lower cladding layer 38 forming a wave-guide. The emission generated in the active layer 36 is guided between the upper cladding layer 34 and the lower cladding layer 38. In order to make wave-guiding possible the refractive index in the active layer 36 is higher than the refractive index of the upper cladding layer 34 and lower cladding layer 38 causing TIR at the interfaces. A uLED with wave-guiding properties as described herein displays enhanced edge emission properties. In a further embodiment a diffraction grating can be etched into the wave-guiding structure that results in enhanced output coupling. FIG. 9 illustrates a uLED 40 with a wave-guide formed by an active layer 42 sandwiched between a upper cladding layer 41 and lower cladding layer 43. A diffraction grating 49 is etched into the wave-guide, for example into the upper cladding layer 41 causing a significant amount of the emission being diffracted out of the semiconductor through the top surface 47.

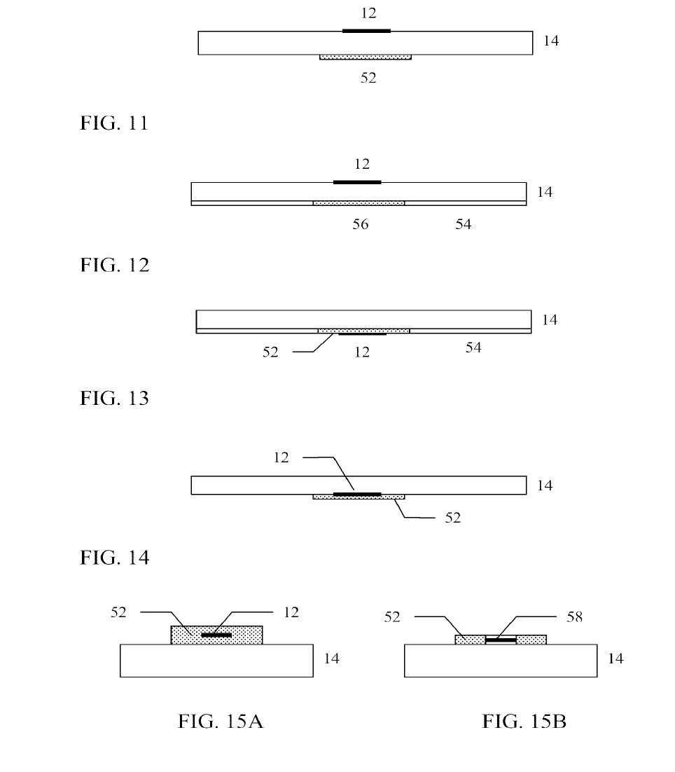

The patterning/roughening of the surface can be achieved through several semiconductor processes including wet etching, photolithography processes, and UV-enhanced wet etching processes (UV illumination can be generated on the surface of the chip that will create localized etching). A conventional UV-activated process known to those skilled in the art might be used to pattern the underside of suspended and release-etched chips. As shown in FIG. 10A, epitaxial layer 44 is irradiated by UV radiation 46, which initiates a chemical reaction between layer 44 and etchant 48 during the wet etching process. Upon removal of the sacrificial layer 48, surface 50 of layer 44 is roughened (FIG. 10B).

C. Mirror Layers—Reflective materials, such as aluminum and silver, can also be used in order to direct the light generated in the die toward a specific surface without incurring significant loss. Reflective materials can be greater than 90% reflective and can be properly designed to match the emission spectrum that is generated by the die. Reflective materials can be added to the die pre- or post-roughening, as described above, in order to reduce the losses in the die. Reflectors can be used to coat all or a portion of the planar surfaces of the die. As well, reflector material can be provided to the top surface of the die to create a bottom-side emitting die or to the bottom surface of the die to create a top-side emitting die.

### Feature 2—Optics and Phosphors

The use of uLEDs provides a distinct advantage from an optical/phosphor point of view. As optics scale with the size of the source, the use of very small die provides opportunities for very small optics, which can be integrated in the package 10 easily and cost effectively. As well, the application of the phosphors used to convert the light generated by the die to white light also scale with the die. This provides some options for how the phosphor is integrated into the package 10, and how the correlated color temperature can be more tightly controlled.

There are several means and approaches to applying phosphor to the system in order to convert the light. In the configuration of the package 10 shown in FIG. 1 the entire second surface 32 of the substrate 14 is coated by the layer 30 of phosphor material. However, in doing this it is often difficult to control the thickness and consistency of the layer 30 of phosphor material, which in turn results in variation of the color produced by the package 10. As well, phosphor materials are relatively expensive and by applying the phosphor layer 30 to the entire panel of the substrate 14, the cost of the package 10 is increased significantly. An alternative approach is to deposit small spots 52 of phosphor material that are localized to where the dice 12 are located, as seen in FIG. 11. The material can be deposited in a variety of manners including inkjet deposition, dispensing a larger dot of material, etc. However, those methods make it difficult to control the consistency and thickness of the phosphor material. An alternative approach that can be used is to print the material thereon by employing a screen (not shown). The thickness of the material would be set by the thickness of the screen (FIG. 11).

Another approach is to apply a mask material 54 to the substrate 14 that has cutouts 56 formed that define where the phosphor would be applied to the substrate 14 (FIG. 12), and the phosphor would be dragged across the surface by a doctor blade to set it in place. Another similar approach is to dispense a small amount of phosphor material in each cutout 56, allow the phosphor to dry, then polish or scrape the surface to remove any excess, leaving the cutout 56 accurately filled.

The above techniques can also be used to apply the phosphor directly to the die, either by depositing the phosphor 52 and placing the die 12 on it (FIG. 13), or by placing the die and applying phosphor over top of it (FIG. 14). As well, for a case where the uLED 12 emits in both the upward and downward directions, the phosphor 52 can be applied both above and below the die 12 (FIG. 15A). The same technique can also be used to apply phosphor 52 around the die in the case where an edge-emitting die 58 is used (FIG. 15B).

It is worthwhile to mention that any combination of phosphors and die can be used to produce the desired color of light. It is also understood that although all of the package configurations that are disclosed contain only one die and phosphor in one location, that several die of different wavelengths and different phosphors can be combined to produce any color. As well, die can be individually addressable which would enable color controllability as well as color tunability. For example, red, green and blue uLEDs could be combined without a phosphor to create a color tunable solution and could also produce white light. Another example is to use a warm white phosphor combined with a blue and a green uLED. The package 10 can then produce any color in the gamut that is defined by those three points in the color space. Another example is to have a blue uLED and a phosphor designed to produce cool white and combine it with a red uLED to produce warm white. The uLEDs typically range in size from approximately 25-300 um. This form factor for a die allows for new optical concepts that can be highly compact and provide beam shaping for the light emitted by the die, or phosphor or both. Generally, the combination of reflectors and optics can provide the beam shaping to achieve the desired effect.

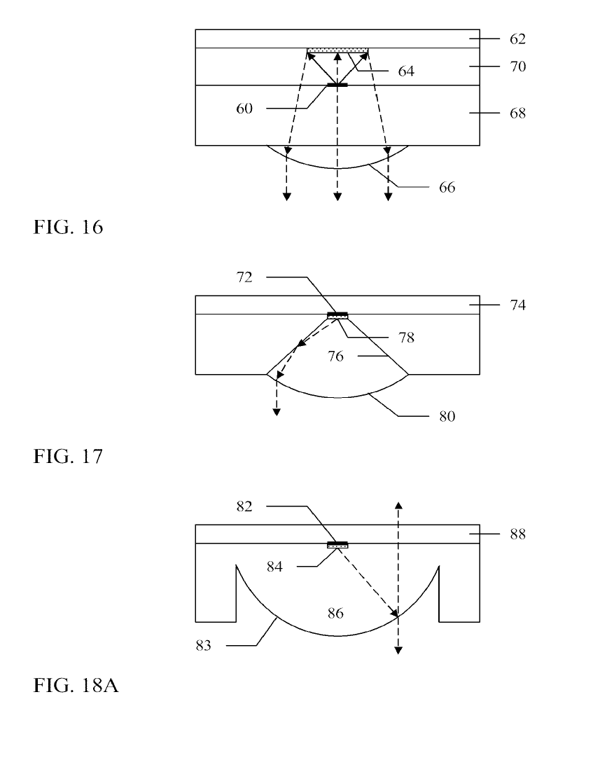

In one embodiment seen in FIG. 16, a top emitting uLED 60 emits onto a remote reflector 62 with a phosphor layer 64 deposited on it that is spaced from the substrate 68 by a gap 70. An optical element 66 is disposed or molded into or onto the transparent substrate 68 in order to shape the light generated by the phosphor layer 64. The gap 70 between remote reflector 62 and substrate 68 may be air or an optically transparent material.

In another embodiment seen in FIG. 17, a top emitting uLED 72 is mounted on a reflective surface 74. A mirror layer 76, using materials such as aluminum or silver, is formed in an encapsulation. The phosphor layer 78 can be deposited either directly on the chip, or placed remotely or at a distance from the chip. As well, an optical lens 80 can be included to shape the light generated by the combined uLED/phosphor.

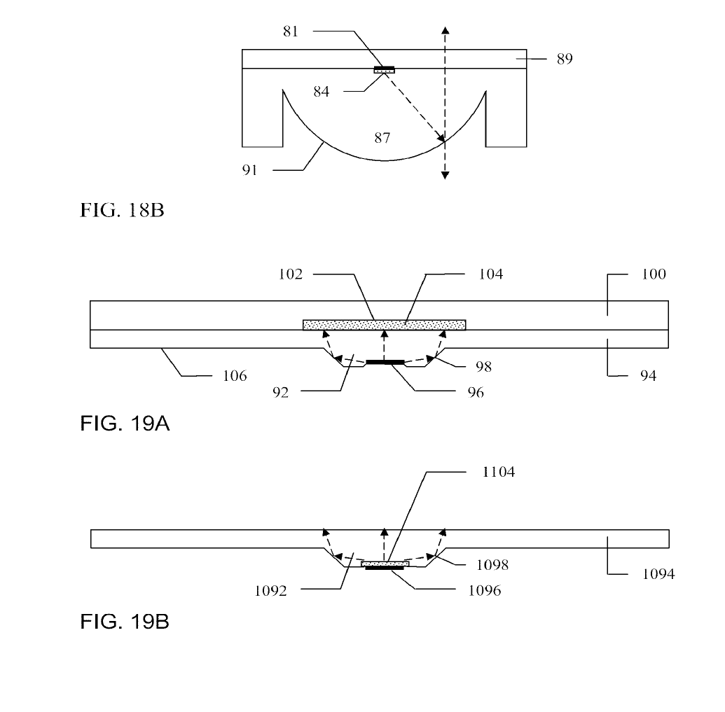

In another embodiment seen in FIG. 18A, a top emitting uLED 82 can be mounted on a substrate 88. Optics 86 with a pre-deposited region 84 of phosphor material may then be disposed on, or integrated with, the substrate 88. The optics 86 may have a reflective or partially reflective coating 83 applied to it to direct the light either up or down as desired. The reflective layer can also be designed to reflect specific wavelengths or series of wavelengths as is desired. Alternatively as seen in FIG. 18B a bottom emitting uLED 81 is mounted on a substrate 87 on top of a pre-deposited region 84 of phosphor. Encapsulation 89 is applied. The substrate 87 may provide optical functions 91 such as beam shaping and may be reflective or partially reflective coated.

Regarding the package 10 in FIG. 1, due to the difference in refractive index between the surface of the uLED 12 (approximately 2.3 for InGaN uLEDs) and the transparent material of the substrate 14 (approximately 1.5 for glass and PMMA plastic) the light produced from the uLED 12 includes portions of radiant flux emitted at oblique angles that undergo total internal reflection (TIR) at the opposite surface 32 of the substrate 14, and thus may be absorbed rather than exiting from the substrate 14. To substantially reduce TIR losses, an optical structure may be incorporated into the transparent substrate 14 such that radiant flux portions emitted at oblique angles from the uLED surface are preferentially redirected towards the normal of the substrate surface 32, thereby minimizing TIR losses and maximizing luminous efficacy.

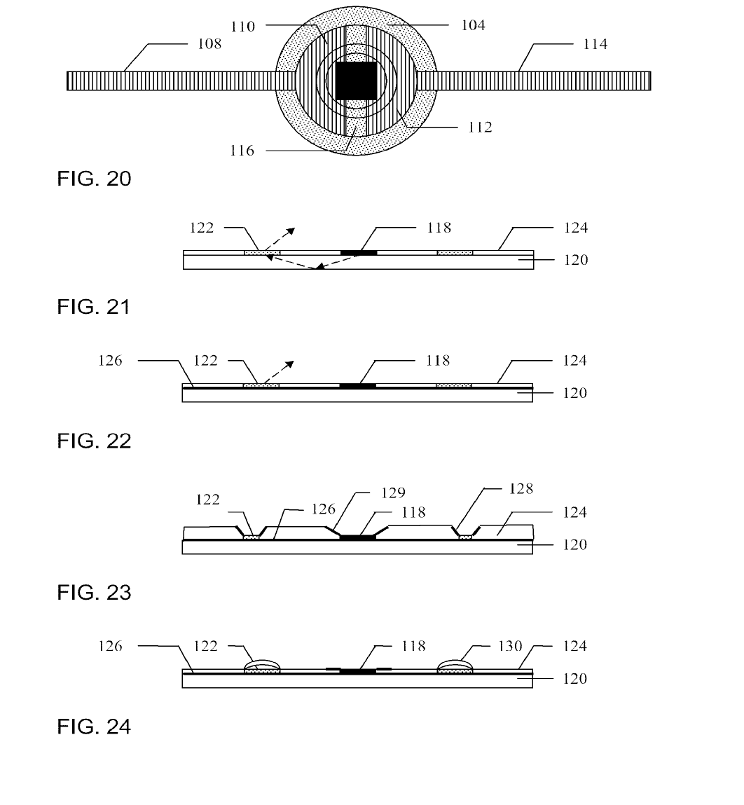

More particularly, as seen in FIGS. 19A, 19B and 20, the optical structure for reducing TIR losses is a molded feature in the form of a mesa created on a transparent substrate. The uLED is placed directly upon the mesa, as shown in FIG. 19A, or placed on a fluorescent or phosphorescent layer pre-deposited on the mesa, as shown in FIG. 19B. The mesa is coated with substance to create a reflector, or designed to use TIR and direct the light entering the mesa.

As shown in FIG. 19A, the uLED 96 is mounted on the mesa 92 that is integrally molded on a first optically transparent substrate 94. The uLED 96 is applied by using for example a transfer printing technique. The mesa 92 is configured such that the emission of radiant flux from the uLED (indicated by rays 98) is substantially transmitted through the first substrate 94. A second optically transparent substrate 100 having a depression 102, molded therein and centered or aligned above the mesa 92 of the first substrate 94, is filled with a fluorescent or phosphorescent material 104 such as cerium-activated yttrium-aluminum-garnet (YAG:Ce) in an optically transparent binder and optically connected to the first optically transparent substrate 94.

As shown in FIG. 20, metallic interconnects 108, 110, 112 and 114 are applied to the lower surface 106 of the first transparent substrate 94 (FIG. 19A), thereby providing anodic and cathodic connections to the uLED 96. The interconnects may be applied by evaporative deposition of a suitable metal or metallic compound, or may be a conductive ink such as silver nanoparticles in a polymeric binder that is applied by means of flexographic or inkjet printing techniques and then sintered to provide substantially metallic interconnects. The metallic interconnects 110, 112 are applied to the walls and top surface of the integrally molded mesa 92, thereby performing the secondary function of providing reflective mirrors at 110, 112 that redirect substantially oblique emission from the uLED 96 towards remote phosphor material 104. A physical gap 116 electrically separates the interconnects 110, 112 from one another.

The reflective mirrors provided by portions of the interconnects 110, 112 on the mesa 92 substantially and advantageously increase the luminous efficacy of the remote phosphor by preferentially redirecting emission of radiant flux from the uLED 96 towards the normal direction of the opposite side of the first transparent substrate 94. Due to the redirection of radiant flux emitted obliquely by uLED 96, the problem of total internal reflection of the flux within the first substrate 94 is avoided. Further, the width of depression 102 need not extend beyond the region of incident radiant flux, thereby minimizing the quantity of phosphorescent material 104 required for example to produce nominally white light.

Alternatively displayed in FIG. 19B a bottom emitting uLED 1096 is mounted on top of a fluorescent or phosphorescent material 1104 that has been pre-deposited on the mesa 1092. The mesa 1092 is integrally molded on a first optically transparent substrate 1094. The uLED 1096 is applied by using for example a transfer printing technique. The mesa 1092 can be configured to provide to provide beam shaping (indicated by rays 1098) and reduction of TIR losses of radiant flux exiting the fluorescent or phosphorescent material 1104.

As in the embodiment displayed in FIG. 19A and FIG. 20 the mesa might utilize TIR to control the light emission or may be coated with reflective material. In the case that a metal reflector is utilized the reflector material may also serve as electrical interconnects.

A current calculation of uLED system performance suggests dice spacing on the order of approximately 5 to 10 mm to achieve comparable performance to a fluorescent troffer luminaire. Point sources at this spacing will leave a visual effect of point emitters if no specific optical strategies are used to achieve the appearance of a uniform light source. In addition to the fact that individual point sources are visible, the chromaticity and flux variation between the individual chips will be visible.

In another embodiment shown in FIG. 21, an edge emitting uLED 118 is mounted on substrate 120 with substrate 120 and planarization layer 124 acting as a waveguide through which the light generated by the uLED 118 will be transmitted. Phosphor material 122 is placed in desirable locations throughout the waveguide. The phosphor absorbs the uLED light and re-emits the light thereby out-coupling it from the waveguide. In this configuration substrate 120 and planarization layer 124 becomes a waveguide with specific phosphor scatter center that will couple out the white light generated. The density of the phosphor dots can be significantly larger than the density of the uLEDs, creating a homogenous emission appearance. In this configuration, the phosphor will also be excited from various uLED sources creating a mixing effect which will reduce colour and brightness variations that might exist. Care must be taken with the quality of the planarization layer 124 to avoid scattering of the emission in non-desirable regions. In this embodiment, some of the emission of the LED will not be subject to total internal reflection and will escape out of the system prior to striking the phosphor.

In another embodiment shown in FIG. 22, the uLEDs are assembled into the system in such a way that all the emission will be guided by total internal reflection into the waveguide. Further to this embodiment, the substrate 120 may be reflectively coated with a reflective material 126, thereby creating a one sided emitter system. As well, further optical elements as shown in FIGS. 23 and 24 can be added around the out-coupling points to enhance light extraction and/or provide beam control of the emitted light. For example, in FIG. 23 mirrors 129 may be applied to the optical planarization layer that may increase the TIR coupling of light emitted by the edge emitting uLEDs 118 into the planarization layer 124. Furthermore mirrors 128 may be applied to direct the light emitted by the side emitting uLEDs 118 to the phosphor extraction points 122 and or shape light emitted by the phosphor extraction points 122 exiting the package. In FIG. 24, lenslets 130 perform a similar function.

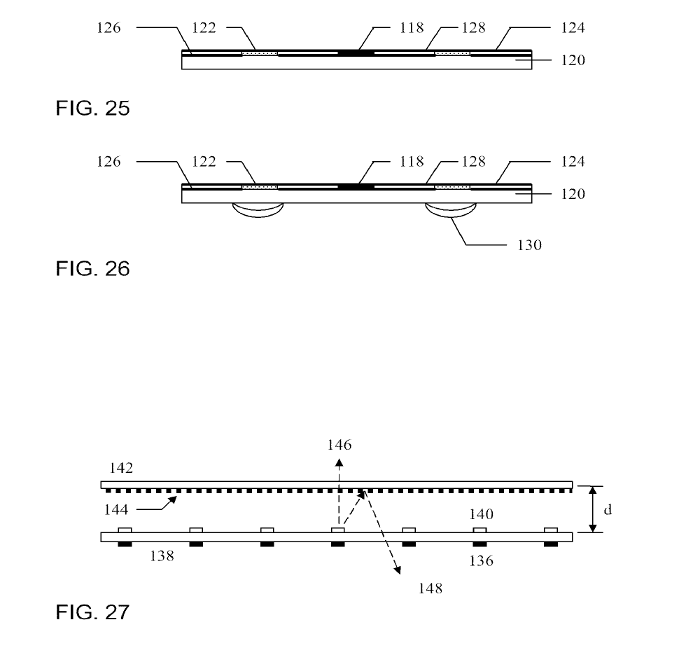

In another embodiment shown in FIGS. 25 and 26, either or both the substrate 120 and the planarization layer 124 may be coated with a reflective material 126, and only desired areas where the phosphor is deposited are not reflectively coated. The lens arrays 130 or other means to shape or enhance the output beam may be disposed on the substrate 120 (FIG. 26).

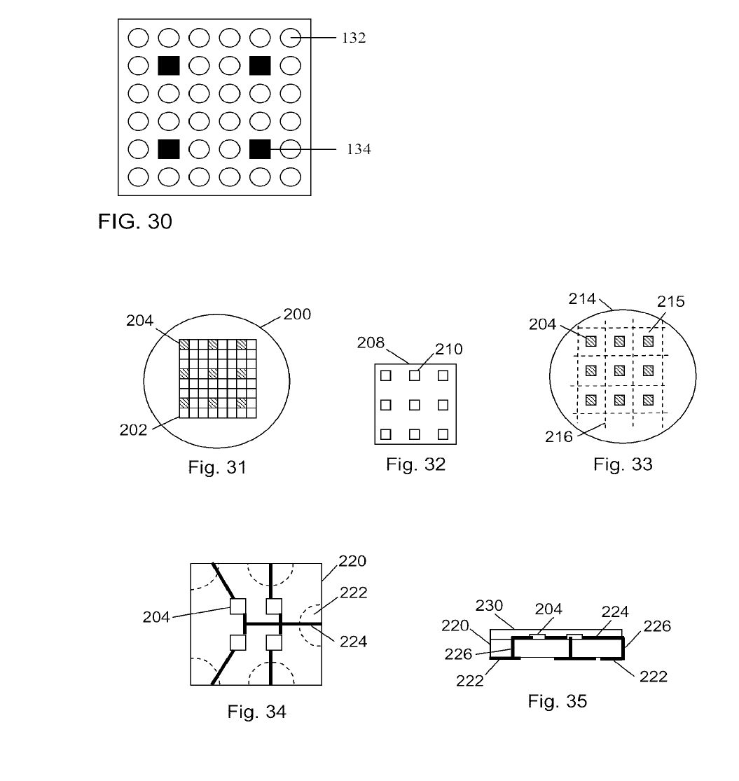

In another embodiment shown in FIG. 30, the distribution and size of the phosphor dots 132 with respect to uLEDs 134 is optimized for efficient light extraction and uniformity. For example, it may be desirable to increase the phosphor dot size in regions where low irradiance due to the uLEDs is present.

In another embodiment, holographic diffusers, such as commercially available under the trade name Light Shaping Diffusers from Luminit (Torrance, Calif.) with transmittances of approximately 85 percent can be used to provide an even distribution of luminance across the surface of the diffuser. These diffusers could be laminated to either the top or bottom surface of the package 10 (FIG. 1). A reflective material, such as Vikuiti display film from 3M (St. Paul, Minn.), could also be laminated in such a fashion.

For many general illumination applications, such as for example office lighting, it is desirable to employ luminaires that exhibit diffuse light emission into both hemispheres. Such luminaires are often referred to as having a “direct/indirect” distribution in that they provide both direct illumination and indirect illumination reflected for example from the office ceiling.

FIG. 27 depicts an array of uLEDs 136 mounted on transparent substrate 138 such that the emission of light from the LEDs is substantially transmitted through the substrate. An array of phosphor dots 140 is deposited onto the opposite side of substrate 138, wherein the density of phosphor in the transparent binder (the phosphor “loading”) is such that the combined emission of the LEDs and phosphor dots comprises white light with a predetermined correlated color temperature. Substrate 138 is separated from transparent substrate 142 by a distance d, wherein d is chosen such that the distribution of illumination on the surface of transparent substrate 142 is substantially even as perceived by the human eye. As an example, an array of uLEDs 136 with a spacing of 8 mm would require a distance d of approximately 10 mm. Transparent substrate 142 is coated on one side with a reflective film 144. Said film has an array of microscopic holes, thereby comprising a “transflector.” When observed from a distance, said transflector appears as a semi-transparent mirror. The ratio of transmittance to reflectance can be varied by varying the diameter of the holes for a predetermined spacing. Light ray 146 intersects a hole in reflective film 144 and so is transmitted through transparent substrate 142. On the other hand, light ray 148 intersects reflective film 144, and so is reflected in the opposite direction through transparent substrate 138.

In practice, the electrical interconnects (not shown) to the uLEDs 136 will be small enough in relationship to the spacing of the uLEDs that they will not be visible when viewed from a reasonable distance, and will not absorb a significant portion of the emitted light. For applications where the interconnects may be visible and objectionable, the assembly shown in FIG. 27 many be arranged such that light ray 146 represents direct illumination (and hence visible), while light ray 148 represents indirect illumination (and hence hidden from the viewer).

With respect to FIG. 27, reflective film 144 may be applied to the opposite side of transparent substrate 142 with no significant change in optical performance of the apparatus. Phosphor dots 140 may be omitted if the uLEDs emit visible light with the desired spectral power distribution. For example, white light-emitting diodes may be fabricated using zinc oxide nanorods, or combinations of uLEDs such as red, green, and blue.

Reflective film 144 may be fabricated by for example vacuum sputtering of aluminum or other reflective metal onto transparent substrate 142, which may be glass or plastic as in known to those skilled in the art. Reflective film 144 may also be fabricated using giant birefringent optical films, with the microscopic holes formed by selective etching or laser ablation of the reflective film. An advantage of giant birefringent optical films are that they are nearly perfect reflectors for wavelengths across the visible spectrum.

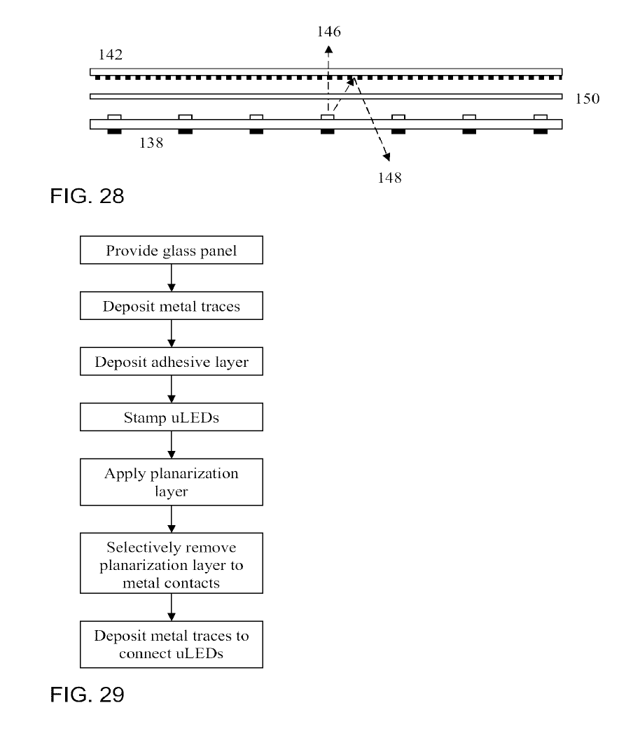

FIG. 28 discloses an alternative embodiment substantially the same as shown in FIG. 27 except that a light concentrating diffuser 150 such as disclosed in U.S. Pat. No. 5,861,990 is disposed between transparent substrates 138 and 142. Diffuser 150 is oriented with its microstructured surface facing transparent substrate 142, such that the diffuse incident illumination from the uLED array and phosphors dots is preferentially redirected (“concentrated”) towards transparent substrate 142. Consequently, light rays incident upon the holes in the reflective film are more collimated than would otherwise be the case. This is a particular advantage for direct/indirect luminaires, where it is often necessary to limit the angle of the light emitted in the downwards direction in order to prevent visual glare.

### Feature 3—Substrate

As mentioned above, there is a great deal of flexibility with the choice of substrate material due to the thermal advantages of uLEDs. This will provide options on the choice of substrate 14 that is used (FIG. 1). Substrates can be flexible, rigid, transparent, opaque, etc. based on the application requirements. Currently, the preferred materials to use are glass and polyethylene terephthalate (PET) plastic because of their mechanical and optical properties. As well, both materials are currently used in high volume manufacturing processes.

Ceramic materials may also be used for the substrates, such as Al₂O₃ (alumina). Metals such as aluminum foil, or oxidized aluminum may also be used. Metal foils may be laminated with plastic films for increased strength.

A substrate may also be a leadframe carrier. A substrate may comprise traces, vias, wrap-around connections or other similar or equivalent features to allow for electrical connection to the uLED chips when integrating uLED packages into systems.

A substrate may comprise silicon and may comprise electronic circuitry such as resistors, capacitors, transistors, diode, zener diodes, etc.

In some embodiments, the uLED substrate does not provide any function other than serving as a carrier to hold and transfer the uLED. Electrical connectivity may be achieved through integration of the uLED into the system via wirebonding directly to the uLED chip, through vacuum metallization processes, or other processes known to people skilled in the art.

One or more uLEDs may be mounted to a substrate with adhesive. The uLED(s) may alternately be mounted to the substrate using a solder reflow process.

There are also opportunities to integrate various optical components into the substrate. Microlenses, graded index lenses, filters, reflectors, waveguides, etc. can be integrated into the substrate material.

MicroLEDS are preferably transferred from a source substrate to a target substrate using a printing or a vacuum pickup process, preferably transferring multiple uLEDs at the same time.

Referring to FIG. 31, a source substrate 200 is shown carrying an array of uLED chips 202. Certain uLEDs 204 are identified to be transferred at the same time using a printing process. In the example shown, every third uLED in the top row, starting from the first, is identified for pickup. Starting from every identified uLED in the top row, every third uLED in these columns is identified for pickup. In other embodiments, every nth uLED may be selected in each square or rectangular sub-array, where n can be any integer equal to 1 or more. FIG. 32 shows a pickup head or stamp 208 with pickup surfaces or pads 210 positioned and spaced in correspondence with positions of the identified uLEDs 204 to be transferred in a single step.

FIG. 33 shows a target substrate 214 with carriers 215 defined by break lines 216. The carriers are shown carrying the uLEDs 204 that were identified in FIG. 31 and that have been transferred from the source substrate 200 to the target substrate 214. The spacing of the uLEDs on the target substrate corresponds to the spacing of the identified uLEDs 204 on the source substrate 200. In the embodiment of FIG. 33, only one uLED 204 has been shown on each carrier 215. In other embodiments, two or more uLEDs may be transferred to each carrier in two or more transfer steps.

Preferably, all further processing steps are carried out after the uLEDs have been transferred to the target substrate 214. Such processing steps may include metallization, wirebonding, encapsulation and/or phosphor application. These steps are preferably performed before the target substrate 214 is broken along break lines 216 into individual carriers, using a process such as dicing, snapping or other suitable technique known in the industry.

The concurrent processing of a large number of uLEDs in a batch allows the costs of processing to be kept low.

### Feature 4—Interconnects

Interconnects pose a challenge to the use of uLEDs. Due to the small size of the chips, the ohmic contacts that are formed on the die must also be small. This makes traditional interconnect methods, such as a wirebonding approach, very difficult, especially once assembly tolerances are considered. For a horizontal structured chip with n-type and p-type contacts on the same side of the chip, the problem is made worse because one of the contacts will remove light emitting material, and there is more opportunity for electrical shorting as the contacts will be very close to each other. As such, a very accurate interconnect method is required for uLEDs. In practice, the electrical interconnects to the uLEDs will be small enough in relationship to the spacing of the uLEDs that they will not be visible when viewed from a reasonable distance, and will not absorb a significant portion of the emitted light.

Referring to FIG. 1, one advantageous approach is to pre-deposit the conductive traces 16 on the substrate 14, then use flip-chip methods to align the contacts 28 on the uLED die 12 to the contacts 18 on the traces 16, and bond the die. Several methods could be used to bond the die, including but not limited to thermosonic bonding, eutectic bonding, or epoxy bonding.

Another approach would be to use a vacuum based deposition and photolithography processes in order to form interconnects. A process flowchart of how this may occur is shown in FIG. 29. Sub-micron accuracies are effectively achieved using photolithography. As well, using similar equipment and processes that exist for manufacturing displays, large substrates of up to approximately 2 meters by 2 meters could be processed, which would make the solution cost competitive. As well, there are other advantages to this approach. A photolithography process to apply the interconnects allows almost any pattern to be generated on top of the planarization layer. This could include some optical elements such as reflectors that are mentioned in the optics section. For example, the fill factor or thickness of the metallization could be adjusted to create a complete or partial mirror, allowing some light to pass through while the rest is reflected. Also, many features could be created in the planarization layer that could be metallized to create mirrors to help with light extraction and beam shaping.

As an example, the planarization material could be an optically transparent thermosetting epoxy or ultraviolet-curable photopolymer that are subsequently metallized by vacuum deposition or electroplating to create an optically reflective layer. Said reflective layer could then optionally be etched to for example create an array of microscopic holes to create a transflector material. Alternatively, the planarization layer can be masked during vacuum deposition or electroplating to provide a reflective layer in selected regions only, such as in the immediate vicinity of the uLED dice.

In yet another alternative approach, an inkjet process is used to create the interconnects, wherein the ink material comprises conductive particles such as silver or carbon nanotubes in a polymer solution. The ink is loaded into an inkjet printing machine that is capable of depositing small dot sizes. Following planarization of the die, the interconnects are deposited onto the top surface of the package. Depending on the conductivity of the ink, the printed traces may be connected to pre-deposited conductive traces composed of metal, indium-tin oxide traces (ITO), graphene, carbon nanotubes, or other materials, on the substrate.

A further process to create interconnects utilizes screen printing technology.

Referring to FIG. 34, a top view of a singularized carrier 220 is shown with four transferred uLEDs 204 in a square array. The carrier may be made of ceramic, such as Al₂O₃. Electrically conductive traces 224 are present on the carrier, and may provide electrical connection to the uLED chips 204 in the same way that connections are made in FIG. 1. In the example of FIG. 34, each of the four uLEDs 204 may be driven separately. Other connection arrangements are possible, whether they be serial, parallel or a mixture of both, and other components may also be included. On the underside of the carrier 220 there are electrical connection pads 222, for connection to circuitry and/or traces external to the carrier. FIG. 35 shows a side view of the carrier 220. Electrically conductive traces 224 on the upper surface of the ceramic carrier 220 continue or are connected to wraparound traces or wires 226 on the sides of the carrier, which in turn continue or are connected to electrically conductive pads 222 on the lower side of the carrier. A pad may have a linear dimension of several tens of μm, for example. On the upper surface of the carrier 220 there is an encapsulation layer 230. Instead of an encapsulation layer, there may be a planarization layer.

### Feature 5—System

In addition to light emitting devices, the package 10 (FIG. 1) could also incorporate various other electrical components that would be used to drive, control or provide feedback for, the light emitting devices. For example, zener diodes or transistor components could be placed adjacent to the uLED(s) in the package to drive, protect, or control the current flow through the system. The components could be stacked upon each other, depending on the configuration of the uLEDs. Interconnects as described above could also be used to form electrical connections between components.

For simplicity sake, most of the drawing figures display a single uLED. It is understood that the one uLED is a part of a larger array on a potentially large sheet, though single uLED processing could also be used.

### Example Packages

Referring again to FIG. 34, the package shown with four uLEDs may be a RRGB package, in that it comprises two red uLEDs, a green uLED and a blue uLED. Alternate packages with four uLEDs may comprise RGGB, RGBB or RAGB (red-amber-green-blue) sets of uLEDs. Still other combinations are possible, that include one or more warm white, cool white, violet, yellow, infrared, ultraviolet and/or any other wavelength of uLED.

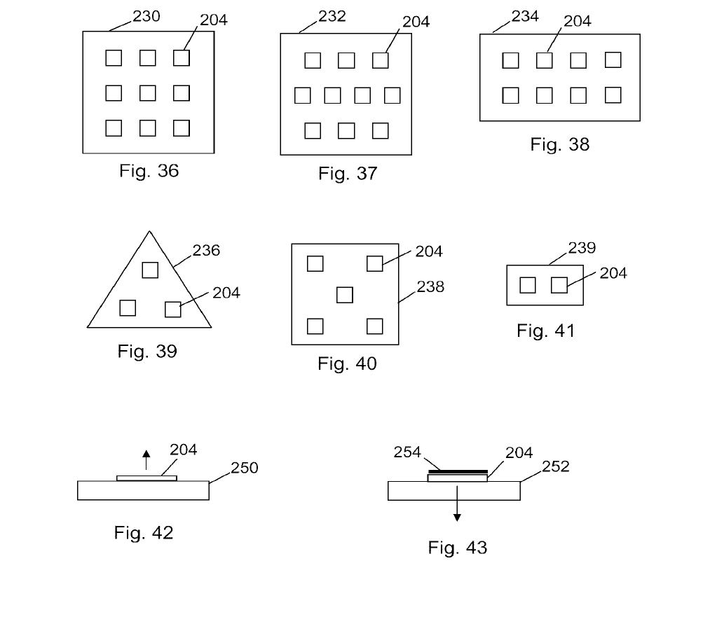

Referring to FIG. 36, a square package 230 is shown with an array of nine uLEDs 204 that have been transferred from a source substrate. This package, for example, may comprise three red, three green and three blue uLEDs. Of course, other combinations of red, green and blue, and/or other colours or wavelengths may be used in the package 230. By including more than one uLED of nominally the same colour, an averaging of wavelengths can be achieved, resulting in a narrower chromaticity spread between nominally similar packages.

FIG. 37 shows a square package 232 which carries ten uLEDs 204. Again, the uLEDs may all be different colours or groups of one or more uLEDs may have nominally the same colour. For example, there may be five warm white uLEDS and five cool white uLEDs, or there may be three red, three green, two blue and two amber uLEDs. Similar wavelength uLEDs may be positioned adjacent to each other on the package or they may be separated by intervening uLEDs.

FIG. 38 shows a rectangular package 234 with eight uLEDs 204. FIG. 39 shows a triangular package 236 with three uLEDs 204. FIG. 40 shows a square package 238 with five uLEDs 204. FIG. 41 shows a rectangular package 239 with two uLEDs 204.

Packages do not need to be restricted to the shapes or aspect ratios shown herein, and may be other shapes, including non-regular shapes.

FIG. 42 shows a single uLED chip package in which the substrate is aluminum foil 250. The use of uLEDs and foil permits the overall thickness of the uLED package to be as low as 50 to 100 μm, although thicknesses outside this range are also possible. Light is emitted upwards from the upper surface of the uLED chip 204. Other foils may be used, such as tin or alloys. In packages with electrically conductive substrate, the substrate itself can provide one of the electrical connections to the uLED(s). A second or further contacts may be made when integrating these ultrathin packages into systems.

FIG. 43 shows a bottom emission uLED package. uLED 204 is mounted on a substrate 252 made from glass, transparent plastic or other transparent or translucent material. Reflector 254 is placed on top of uLED 204 to reflect any upwardly emitted light downwards. The reflective layer 254 may carry one or more electrical contact pads for supplying current to the uLED.

As well as the small individual packages described above, larger, sheet-format packages may be made, in which there can be considerably higher numbers of uLEDs. Sheet substrates may be foil-based or plastic, or a lamination of the two, and may contain traces for electrical connectivity.

In the description herein, exemplary embodiments disclosing specific details have been set forth in order to provide a thorough understanding of the invention, and not to provide limitation. However, it will be clear to one having skill in the art that other embodiments according to the present teachings are possible that are within the scope of the invention disclosed. All parameters, dimensions, materials and configurations described herein are examples only and actual values of such depend on the specific embodiment.

What is claimed is:

1.-27. (canceled)

28. A package comprising:
a plurality of side-emitting lighting devices each having electrical contact points;
a flexible substrate for supporting the lighting devices;
a plurality of electrically conductive traces defined on the substrate and electrically connected to the contact points of the lighting devices;
an adhesive layer mounting each of the lighting devices on the substrate;
a planarization layer disposed over the plurality of electrically conductive traces, the planarization layer being (i) substantially transparent to light emitted by the lighting devices and (ii) positioned to guide light emitted from the sides of the plurality of lighting devices into the planarization layer;
a plurality of spaced-apart phosphor elements positioned to receive light from the planarization layer; and
one or more optical elements for receiving light from the phosphor elements, shaping the received light via transmission through the optical element, and emitting the light.

29. The package of claim 28, wherein substantially all of the light emitted by the lighting devices is guided by total internal reflection into the planarization layer.

30. The package of claim 29, further comprising, disposed (i) between the substrate and the planarization layer and (ii) over at least a portion of the substrate, a reflective layer to reduce light transmission into the substrate in the region of the reflective layer.

31. The package of claim 28, further comprising, disposed over at least a portion of the planarization layer, a reflective layer to reduce light transmission out of the planarization layer in the region of the reflective layer.

32. The package of claim 32, wherein the planarization layer comprises at least two non-coplanar portions, the reflective layer being disposed over at least one of the portions.

33. The package of claim 28, further comprising:
a first reflective layer disposed (i) between the substrate and the planarization layer and (ii) over at least a portion of the substrate; and
a second reflective layer disposed over at least a portion of the planarization layer,
wherein at least one of the first or second reflective layers defines openings therethrough from which light is emitted from the planarization layer.

34. The package of claim 28, wherein the substrate comprises a metal foil.

35. The package of claim 28, wherein the substrate is transparent.

36. The package of claim 28, wherein a surface of each of the lighting devices proximate the substrate forms a reflector for reflecting light away from the substrate.

37. The package of claim 28, wherein the substrate comprises at least one of plastic or polyethylene terephthalate.

38. The package of claim 28, further comprising a diffuser disposed above the one or more lighting devices.

39. The package of claim 28, wherein at least one optical element comprises a micro-optic.

40. The package of claim 28, wherein a quantity of the phosphor elements is greater than a quantity of the lighting devices.

41. The package of claim 28, further comprising an encapsulation layer distinct from the planarization layer, the encapsulation layer being disposed over the planarization layer.

42. The package of claim 28, further comprising one or more light-receiving devices disposed over the substrate.

43. The package of claim 42, wherein at least one light-receiving device comprises a photovoltaic cell, a photo sensor, or a solar thermal pickup.

44. The package of claim 28, further comprising, associated with a phosphor element, an out-coupling element for enhancing out-coupling of light from the phosphor element.

45. The package of claim 44, wherein the out-coupling element comprises a mirror.

46. The package of claim 44, wherein the out-coupling element comprises a grating formed in the phosphor element.
